(19) United States
(12) Patent Application Publication
(10) Pub. No.: US 2016/0093562 A1
(43) Pub. Date: Mar. 31, 2016

(54) NON-INSULATED POWER SEMICONDUCTOR MODULE AND METHOD OF MANUFACTURING THE SAME

(71) Applicant: HYUNDAI MOBIS CO.M LTD., Seoul (KR)

(72) Inventor: Jae-Bum KIM, Suwon-si (KR)

(73) Assignee: HYUNDAI MOBIS CO., LTD., Seoul (KR)

(21) Appl. No.: 14/857,264

(22) Filed: Sep. 17, 2015

(30) Foreign Application Priority Data
Sep. 30, 2014 (KR) 10-2014-0131275

(51) Int. Cl. H01L 23/495; H01L 23/528; H01L 21/48; H01L 25/065; H01L 21/56; H01L 23/492; H01L 25/00

(52) U.S. Cl. CPC H01L 23/49586; H01L 23/492; H01L 23/5286; H01L 25/50; H01L 23/4952; H01L 23/49579; H01L 23/49575; H01L 23/49558; H01L 25/0655; H01L 21/563; H01L 21/4875; H01L 21/4889; H01L 21/4825; H01L 21/4803

(57) ABSTRACT

A non-insulated power semiconductor module may include a housing, at least a pair of lead frames fixedly seated in the housing and having a plurality of power semiconductor chips mounted on surfaces thereof, and an insulation member disposed between the housing and the pair of lead frames.

### CROSS-REFERENCE(S) TO RELATED APPLICATIONS

This application claims priority to Korean Patent Application No(s). 10-2014-0131275 filed on Sep. 30, 2014 in the Korean Intellectual Property Office, which is (are) incorporated herein by reference in its (their) entirety.

### BACKGROUND OF THE INVENTION

1. Field of the Invention

Exemplary aspects of the present invention relate to a power semiconductor module for a vehicle and to a non-insulated power semiconductor module with a non-insulated integral bus bar structure and a method of manufacturing the same.

2. Description of Related Art

In general, a power semiconductor module is implemented in a manner of packaging a power device having high current density so as to have an insulation structure having low thermal resistance, in order to prevent heat deterioration and realize high power and high heat dissipation.

FIG. 1 is a view illustrating a typical power semiconductor module having an insulation structure using a ceramic substrate, implemented in the packaging manner. Referring to FIG. 1, a power semiconductor module 10 has a cross-sectional cooling structure in which the ceramic substrate is laminated on a copper (Cu)-made base substrate 120 on a surface of a housing 110 by a soldering portion 131.

The ceramic substrate laminated on the base substrate 120 is designed such that copper (Cu) layers 120 and 150 are formed on upper and lower surfaces of an insulator layer 140 and heat is better transferred downward.

A power semiconductor chip 160 is laminated on the ceramic substrate by a soldering portion 161 and is connected to electrode terminals 170 or the like in a wire bonding manner for circuit connection therewith. In addition, a housing is provided for chip protection and insulation. The housing is made of a material such as an application material or a silicone gel.

However, the power semiconductor module having the insulation structure using the ceramic substrate has a limit to implementation of a compact/high heat dissipation package due to thermal resistance of the insulated ceramic substrate and/or material thereof.

In addition, it is disadvantageous in that a thermal resistance component blocking heat transfer is increased due to non-conductive material characteristics of the insulator layer 140 itself. For this reason, a substrate made of a ceramic material (Al₂O₃ or AlN) having high insulating properties and low thermal resistance is preferred. Moreover, a substrate including an insulator having a small thickness is preferred.

The typical power semiconductor module having the insulation structure using the ceramic substrate has a limit to implementation of a high heat dissipation package having high current density due to limits of the material and package structure.

### SUMMARY OF THE INVENTION

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

An aspect of the present invention is directed to a power semiconductor module with a non-insulation structure without a ceramic substrate and a method of manufacturing the same.

Another aspect of the present invention is directed to a compact/high heat dissipation power semiconductor module of an inverter system for driving a micro-hybrid starter/generator, and a method of manufacturing the same.

Other objects and advantages of the present invention can be understood by the following description, and become apparent with reference to the aspects of the present invention. Also, it is obvious to those skilled in the art to which the present invention pertains that the objects and advantages of the present invention can be realized by the means as claimed and combinations thereof.

In accordance with an aspect of the present invention, there is provided a power semiconductor module with a non-insulation structure without a ceramic substrate, and the power semiconductor module includes a housing, at least a pair of lead frames fixedly seated in the housing and having a plurality of power semiconductor chips mounted on surfaces thereof, and an insulation member disposed between the housing and the pair of lead frames.

The pair of lead frames may be configured such that electrode terminals and a base plate are integrated with each other.

The pair of lead frames may be configured of a copper bus bar.

Each of the power semiconductor chips may be one of an Field Effect Transistor (FET), a Metal Oxide Semiconductor FET (MOSFET), an Insulated Gate Bipolar Mode Transistor (IGBT), and a power rectification diode.

A plurality of lead application layers may be formed on the surfaces of the pair of lead frames for assembly of the power semiconductor chips, and the power semiconductor chips and the lead application layers may be bonded to each other in a lead soldering manner.

The pair of lead frames may be configured such that input electrode terminals and an output electrode terminal have an integral connection portion.

The pair of lead frames may be configured of an N-type lead frame and a P-type lead frame, a plurality of upper-side power semiconductor chips of the power semiconductor chips may be arranged on the N-type lead frame, and a plurality of lower-side power semiconductor chips of the power semiconductor chips may be arranged on the P-type lead frame.

The upper-side power semiconductor chips and the lower-side power semiconductor chips may be connected to the pair of lead frames in a wire bonding manner.

The pair of lead frames may have a U shape.

Washing may be performed before the chips are connected to the pair of lead frames in the wire bonding manner.

In accordance with another aspect of the present invention, a method of manufacturing a non-insulated power semiconductor module includes preparing at least a pair of lead frames, preparing a housing for fixedly seating the pair of lead frames, installing an insulation member in the housing for insulation between the housing and the pair of lead frames, fixedly seating the pair of lead frames in the housing, and mounting a plurality of power semiconductor chips on surfaces of the pair of lead frames so as to be interconnected.

The mounting a plurality of power semiconductor chips may include forming a plurality of lead application layers on the surfaces of the pair of lead frames for assembly of the power semiconductor chips, and bonding the power semiconductor chips and the lead application layers to each other in a lead soldering manner.

The mounting a plurality of power semiconductor chips may include connecting the upper-side power semiconductor chips and the lower-side power semiconductor chips to the pair of lead frames in a wire bonding manner.

The mounting a plurality of power semiconductor chips may include performing washing before the chips are connected to the pair of lead frames in the wire bonding manner.

### BRIEF DESCRIPTION OF THE DRAWINGS

FIG. 1 is a cross-sectional conceptual view illustrating a structure of a typical power semiconductor module.

FIG. 2 is a cross-sectional conceptual view illustrating a structure of a non-insulated power semiconductor module according to an aspect of the present invention.

FIG. 3 is a flowchart illustrating a process of manufacturing the non-insulated power semiconductor module according to the aspect of the present invention.

FIG. 4 is a cross-sectional view illustrating a pair of lead frames prepared according to a lead frame preparation step illustrated in FIG. 3.

FIG. 5 is a cross-sectional view according to a lead frame fixing housing assembly step illustrated in FIG. 3.

FIG. 6 is a cross-sectional view according to a lead application step illustrated in FIG. 3.

FIG. 7 is a cross-sectional view according to a mounting step illustrated in FIG. 3.

FIG. 8 is a cross-sectional view according to a soldering step illustrated in FIG. 3.

FIG. 9 is a cross-sectional view according to a washing step illustrated in FIG. 3.

FIG. 10 is a cross-sectional view according to a wire bonding step illustrated in FIG. 3.

FIG. 11 is a perspective view illustrating an external appearance of the non-insulated power semiconductor module according to the aspect of the present invention.

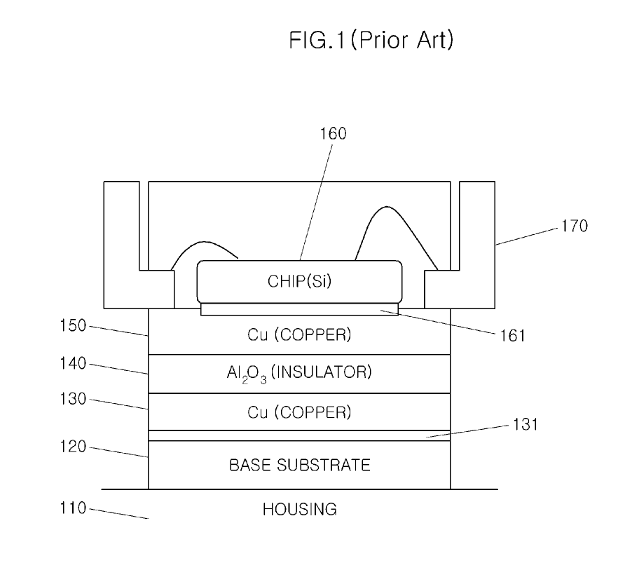

### DETAILED DESCRIPTION

Exemplary aspects of the present invention will be described below in more detail with reference to the accompanying drawings so as to be easily realized by those skilled in the art.

The present invention may, however, be embodied in different forms and should not be construed as limited to the aspects set forth herein. In certain aspects, irrelevant to the present invention may be omitted to avoid obscuring appreciation of the disclosure. Throughout the disclosure, like reference numerals refer to like parts throughout the various figures and aspects of the present invention.

The drawings are not necessarily to scale and in some instances, proportions may have been exaggerated in order to clearly illustrate various layers and regions of the aspects. It will be understood that when an element such as a layer, a film, a region, or a plate is referred to as being “above” another element, it can be “immediately above” the other element or intervening elements may also be present.

In contrast, when an element is referred to as being “immediately above” another element, there are no intervening elements present. In addition, it will be understood that when an element is referred to as being “entirely” formed on another element, it can be formed on the entire surface (or whole surface) of the other element or cannot be formed at a portion of the edge thereof.

Hereinafter, a non-insulated power semiconductor module and a method of manufacturing the same according to exemplary aspects of the present invention will be described in more detail with reference to the accompanying drawings.

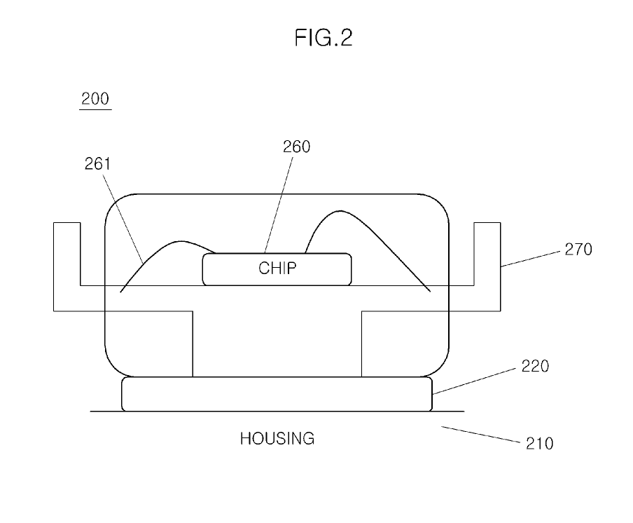

FIG. 2 is a cross-sectional conceptual view illustrating a structure of a non-insulated power semiconductor module 200 according to an aspect of the present invention. Referring to FIG. 2, the power semiconductor module 200 includes a housing 210, a plurality of pairs of lead frames 270 which are fixedly seated in the housing 210 and have a plurality of power semiconductor chips 260 mounted on surfaces thereof, an insulation member 220 disposed between the housing 210 and each of the pairs of lead frames 270, and the like.

The pair of lead frames 270 is configured such that electrode terminals and a base plate are integrated with each other. Accordingly, the pair of lead frames 270 functions as a typical base plate and a ceramic substrate.

In addition, the pair of lead frames 270 is configured of a copper bus bar, and has a U shape for fixing and bending of the housing 210 as an injection molded product. Accordingly, there is no need to form a soldering portion, a ceramic substrate, a base plate, etc. Since the ceramic substrate is not present, the power semiconductor module has a non-insulation structure.

In addition, each of the pairs of lead frames 270 has an integral copper bus bar structure in which the power semiconductor chips 260, input electrode terminals (P and N), and an associated output electrode terminal (U, V, or W) are connected to each other.

The insulation member 220 is disposed between the housing 210 and the pair of lead frames 270 for insulation there between. The insulation member 220 is made of an insulation material (for instance, an insulation sheet, a thermal grease for insulation (gap-filler), or the like) having high thermal conductivity for insulation between the housing 210 and the pair of lead frames 270.

In addition, insert nut insertion and/or bolt fastening structures are formed at the injection molded product for external connection of the input electrode terminals (P and N), and the output electrode terminals (U, V, and W) at tips of the pairs of lead frames 270.

In addition, a gate drive circuit and/or a temperature sensing circuit may be directly bonded to the pairs of lead frames 270 in a soldering manner.

Each of the power semiconductor chips 260 may be one of an Field Effect Transistor (FET), a Metal Oxide Semiconductor FET (MOSFET), an Insulated Gate Bipolar Mode Transistor (IGBT), and a power rectification diode. The power semiconductor chips 260 are configured of upper-side power semiconductor chips and lower-side power semiconductor chips. The power semiconductor chips 260 are connected to the pairs of lead frames 270 through wires 261.

In other words, the power semiconductor module has a structure capable of improving heat dissipation characteristics (that is, having low thermal resistance) by removing the insulator and/or the soldering layer of the ceramic substrate and using the bus bar structure.

In addition, each of the pairs of lead frames 270 has an integral copper bus bar structure capable of functioning as the base plate applied for improvement of heat capacity so as to endure heat generated when high current is applied to the pair of lead frames 270.

In addition, the pair of lead frames 270 has a structure of decreasing contact resistance and increasing allowable current since the input electrode terminals (P and N) and the output electrode terminal (U,V, or W) have an integral connection portion.

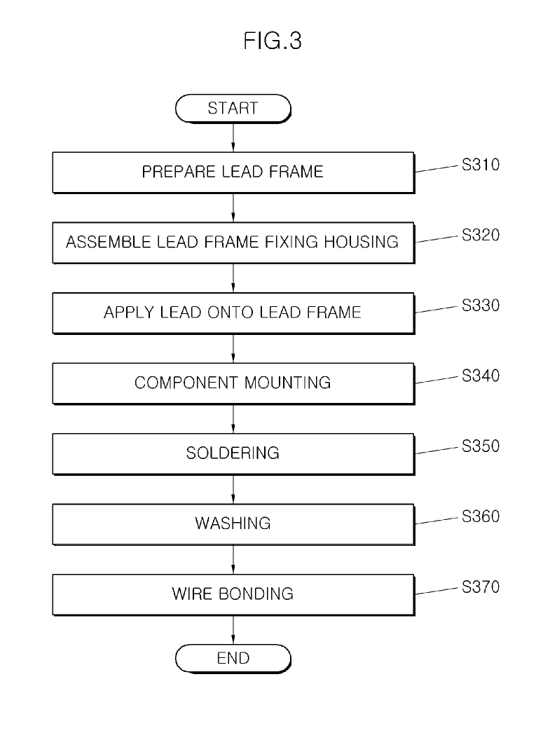

FIG. 3 is a flowchart illustrating a process of manufacturing the non-insulated power semiconductor module according to the aspect of the present invention. Referring to FIG. 3, the pair of lead frames 270 (see FIG. 2) and the housing 210 (see FIG. 2) for fixedly seating the pair of lead frames 270 are prepared (step S310).

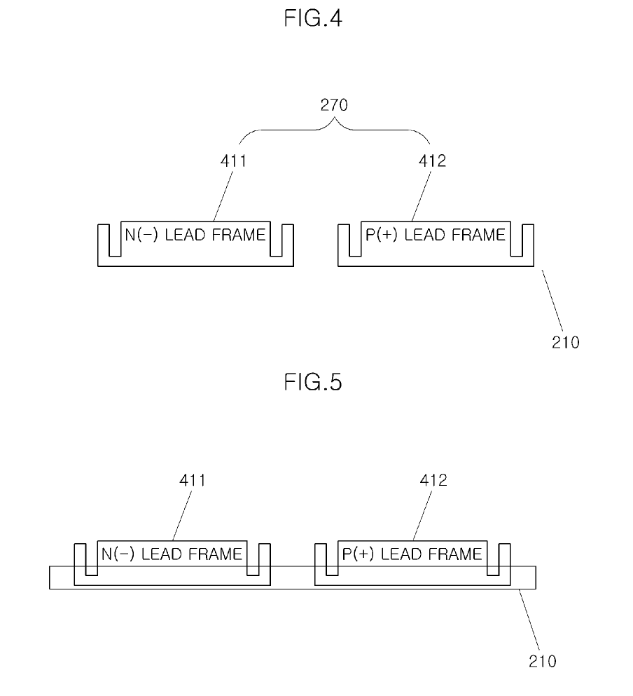

The insulation member 220 (see FIG. 2) is installed in the housing for insulation between the housing 210 and the pair of lead frames 270, and the pair of lead frames 270 is fixedly seated in the housing 210 (step S320). These conceptual states are illustrated in FIGS. 4 and 5, and detailed description thereof will be given below.

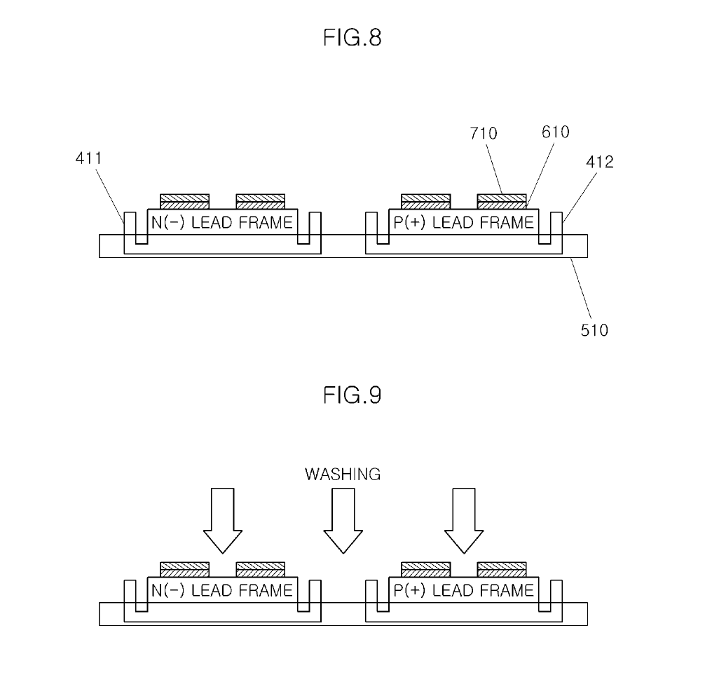

Lead is applied onto the surfaces of the pair of lead frames 270 and the power semiconductor chips 260 (see FIG. 2) are mounted on the surfaces thereof to be connected to each other (steps S330, S340, and S350). In other words, lead application layers are formed by applying lead onto the surfaces of the pair of lead frames 270 for assembly of the power semiconductor chips 260 (step S330). Next, the power semiconductor chips 260 are bonded to the lead application layers in a soldering manner (step S350). These conceptual states are illustrated in FIGS. 7 and 8, and detailed description thereof will be given below.

Next, washing is performed for removing lead flux and/or foreign substances (step S360). This conceptual state is illustrated in FIG. 9.

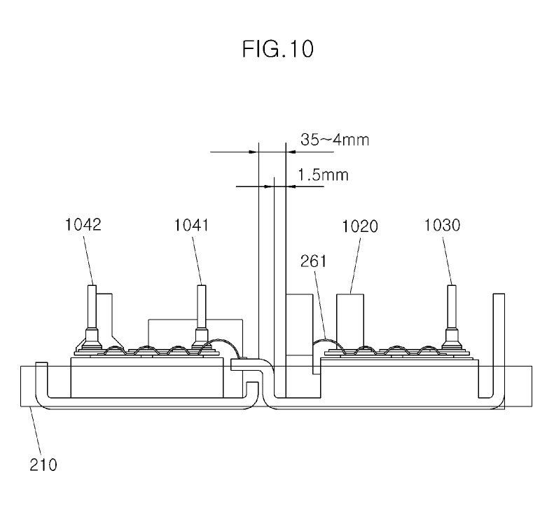

After the washing is performed and a certain time elapses, the power semiconductor chips are connected to the pair of lead frames in a wire bonding manner (step S370). This conceptual state is illustrated in FIG. 10, and detailed description thereof will be given below.

FIG. 4 is a cross-sectional view illustrating the pair of lead frames prepared according to the lead frame preparation step (S310) illustrated in FIG. 3. Referring to FIG. 4, the pair of lead frames 270 is configured of an N-type lead frame 411 and a P-type lead frame 412. Thus, the power semiconductor module has three pairs of lead frames 270 for the output electrode terminals (U, V, and W).

FIG. 5 is a cross-sectional view according to the lead frame fixing housing assembly step (S320) illustrated in FIG. 3. Referring to FIG. 5, the housing 210 as a case is assembled for fixing the N-type lead frame 411 and the P-type lead frame 412. The housing 210 may be injection-molded.

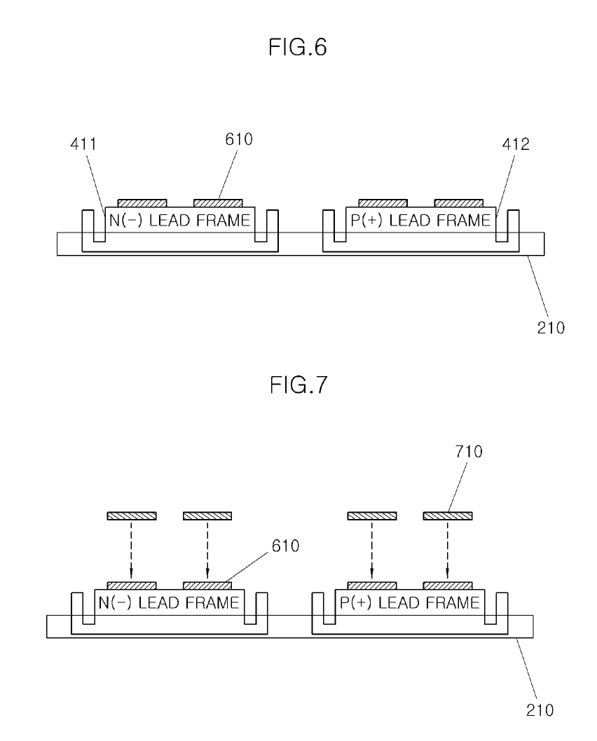

FIG. 6 is a cross-sectional view according to the lead application step (S330) illustrated in FIG. 3. Referring to FIG. 6, the lead application layers 610 are formed on the N-type lead frame 411 and/or the P-type lead frame 412 for assembly of the power semiconductor chips 260 (see FIG. 2).

FIG. 7 is a cross-sectional view according to the mounting step (S340) illustrated in FIG. 3. Referring to FIG. 7, connection terminals 710 of the power semiconductor chips 260 are mounted on the lead application layers 610. In other words, the multiple upper-side power semiconductor chips of the power semiconductor chips 260 (see FIG. 2) are arranged on the N-type lead frame 411 and the multiple lower-side power semiconductor chips of the power semiconductor chips 260 are arranged on the P-type lead frame 412.

FIG. 8 is a cross-sectional view according to the soldering step (S350) illustrated in FIG. 3. Referring to FIG. 8, the connection terminals 710 of the power semiconductor chips 260 may be bonded to the lead application layers 610 in a lead soldering manner. That is, the power semiconductor module has a structure in which the power semiconductor chips are soldered on the copper bus bar. Thus, the power semiconductor module does not have a ceramic substrate (insulator) and has a non-insulated structure in which the upper-side power semiconductor chips and the lower-side power semiconductor chips are not insulated with each other.

FIG. 9 is a cross-sectional view according to the washing step (S360) illustrated in FIG. 3. Referring to FIG. 9, the washing process is performed prior to the wire bonding process. In other words, the washing process is a process of removing lead flux and foreign substances caused by soldering between the power semiconductor chips and the lead application layers.

FIG. 10 is a cross-sectional view according to the wire bonding step (S370) illustrated in FIG. 3. FIG. 10 illustrates a state in which the upper-side power semiconductor chips and the lower-side power semiconductor chips are bonded and connected to each other through the wires 261. That is, FIG. 10 illustrates a state in which the upper-side power semiconductor chips and the lower-side power semiconductor chips are bonded to each other in a wire bonding manner. In the drawing, the associated output electrode terminal (U, V, or W) 1020 is formed at an intermediate position on the N-type lead frame 411 and the P-type lead frame 412 configuring each of the pairs of lead frames.

In addition, the power semiconductor module is equipped with a chip signal connection terminal 1030 for the power semiconductor chip, a first sensor signal connection terminal 1041 for a first temperature sensor, and a second sensor signal connection terminal 1042 for a second temperature sensor.

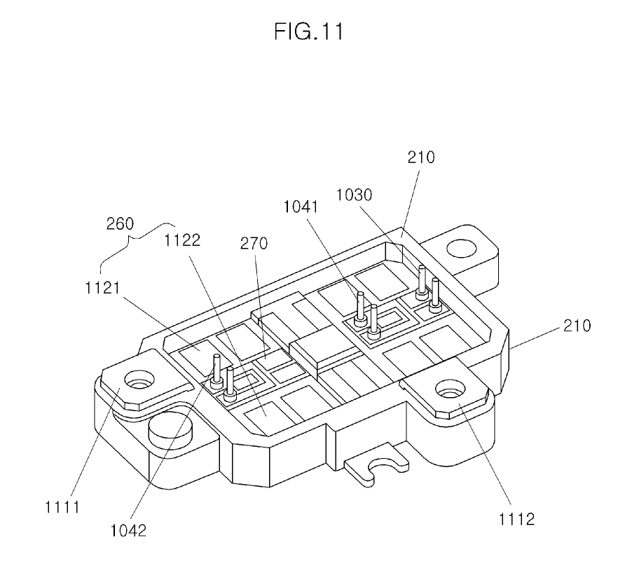

FIG. 11 is a perspective view illustrating an external appearance of the non-insulated power semiconductor module according to the aspect of the present invention. Referring to FIG. 11, the upper-side power semiconductor chips 1121 and the lower-side power semiconductor chips 1122 are arranged on the pair of lead frames 270. In addition, the power semiconductor module is equipped with input terminals 1111 and 1112 and the like. In addition, the insert nut insertion and/or bolt fastening structures are formed at the housing 210 as the injection molded product for external connection of the input electrode terminals and the associated output electrode terminal.

In accordance with the exemplary aspects of the present invention, the present invention can implement a high power/high heat dissipation package for a power semiconductor through a non-insulated heat dissipation structure without using a ceramic substrate.

In addition, the present invention can implement the high heat dissipation package having improved thermal resistance through removal of a soldering portion and/or an insulator.

In addition, the present invention can achieve a compact package through improvement in current density and heat dissipation of a power semiconductor module.

In addition, the present invention can accomplish assembly process improvement and/or material cost reduction by forming at least a pair of lead frames as an integral copper bus bar structure.

While the present invention has been described with respect to the specific aspects, it will be apparent to those skilled in the art that various changes and modifications may be made without departing from the spirit and scope of the invention as defined in the following claims.

What is claimed is:

1. A non-insulated power semiconductor module comprising:
a housing;
at least a pair of lead frames fixedly seated in the housing and having a plurality of power semiconductor chips mounted on surfaces thereof; and
an insulation member disposed between the housing and the pair of lead frames.

2. The non-insulated power semiconductor module of claim 1, wherein the pair of lead frames is configured such that electrode terminals and a base plate are integrated with each other.

3. The non-insulated power semiconductor module of claim 1, wherein the pair of lead frames is configured of a copper bus bar.

4. The non-insulated power semiconductor module of claim 1, wherein each of the power semiconductor chips is one of an Field Effect Transistor (FET), a Metal Oxide Semiconductor FET (MOSFET), an Insulated Gate Bipolar Mode Transistor (IGBT), and a power rectification diode.

5. The non-insulated power semiconductor module of claim 1, wherein a plurality of lead application layers is formed on the surfaces of the pair of lead frames for assembly of the power semiconductor chips, and the power semiconductor chips and the lead application layers are bonded to each other in a lead soldering manner.

6. The non-insulated power semiconductor module of claim 1, wherein the pair of lead frames is configured such that input electrode terminals and an output electrode terminal have an integral connection portion.

7. The non-insulated power semiconductor module of claim 1, wherein the pair of lead frames is configured of an N-type lead frame and a P-type lead frame, a plurality of upper-side power semiconductor chips of the power semiconductor chips is arranged on the N-type lead frame, and a plurality of lower-side power semiconductor chips of the power semiconductor chips is arranged on the P-type lead frame.

8. The non-insulated power semiconductor module of claim 7, wherein the upper-side power semiconductor chips and the lower-side power semiconductor chips are connected to the pair of lead frames in a wire bonding manner.

9. The non-insulated power semiconductor module of claim 1, wherein the pair of lead frames has a U shape.

10. The non-insulated power semiconductor module of claim 8, wherein washing is performed before the chips are connected to the pair of lead frames in the wire bonding manner.

11. A method of manufacturing a non-insulated power semiconductor module, comprising:
preparing at least a pair of lead frames;
preparing a housing for fixedly seating the pair of lead frames;
installing an insulation member in the housing for insulation between the housing and the pair of lead frames;
fixedly seating the pair of lead frames in the housing; and
mounting a plurality of power semiconductor chips on surfaces of the pair of lead frames so as to be interconnected.

12. The method of claim 11, wherein the pair of lead frames is configured such that electrode terminals and a base plate are integrated with each other.

13. The method of claim 11, wherein the pair of lead frames is configured of a copper bus bar.

14. The method of claim 11, wherein each of the power semiconductor chips is one of an Field Effect Transistor (FET), a Metal Oxide Semiconductor FET (MOSFET), an Insulated Gate Bipolar Mode Transistor (IGBT), and a power rectification diode.

15. The method of claim 11, wherein the mounting a plurality of power semiconductor chips comprises:
forming a plurality of lead application layers on the surfaces of the pair of lead frames for assembly of the power semiconductor chips; and
bonding the power semiconductor chips and the lead application layers to each other in a lead soldering manner.

16. The method of claim 11, wherein the pair of lead frames is configured such that input electrode terminals and an output electrode terminal have an integral connection portion.

17. The method of claim 11, wherein the pair of lead frames is configured of an N-type lead frame and a P-type lead frame, a plurality of upper-side power semiconductor chips of the power semiconductor chips is arranged on the N-type lead frame, and a plurality of lower-side power semiconductor chips of the power semiconductor chips is arranged on the P-type lead frame.

18. The method of claim 17, wherein the mounting a plurality of power semiconductor chips comprises connecting the upper-side power semiconductor chips and the lower-side power semiconductor chips to the pair of lead frames in a wire bonding manner.

19. The method of claim 11, wherein the pair of lead frames has a U shape.

20. The method of claim 18, wherein the mounting a plurality of power semiconductor chips comprises performing washing before the chips are connected to the pair of lead frames in the wire bonding manner.
